(19) United States
(12) Patent Application Publication
(10) Pub. No.: US 2026/0005097 A1
(43) Pub. Date: Jan. 1, 2026

(54) HEAT SPREADING AND THERMAL HEAT REMOVAL STRUCTURES

(71) Applicant: International Business Machines Corporation, Armonk, NY (US)

(72) Inventors: John Knickerbocker, Monroe, NY (US); Keiji Matsumoto, Yokohama-shi, Kanagawa-ken (JP); Aakrati Jain, Albany, NY (US); Prabudhya Roy Chowdhury, Albany, NY (US)

(21) Appl. No.: 18/756,772

(22) Filed: Jun. 27, 2024

(51) Int. Cl. H01L 23/373; H01L 23/522; H01L 23/528; H01L 25/065

(52) U.S. Cl. CPC H01L 23/3736; H01L 23/5226; H01L 23/5283; H01L 23/5286; H01L 25/0652; H01L 2225/06541

(57) ABSTRACT

Semiconductor structures are provided in which heat spreading and thermal heat removal are improved by providing one or more heat removal paths in which heat spreading and thermal heat removal occurs leveraging horizontal direction and vertical directions and through reduced resistance of heat removal paths. Notably, heat is spread horizontally to the edges of the semiconductor structures and then the heat is removed vertically (up and/or down) from the semiconductor structures.

### BACKGROUND

The present application relates to semiconductor technology, and more particularly to semiconductor structures that have increased heat spreading and thermal heat removal.

In the semiconductor industry, the removal of heat from semiconductor devices and systems continues to remain a technology challenge that can often limit performance and reliability. Heat generated during the operation of the semiconductor device needs to be efficiently removed in order to minimize the rise in the temperature of the semiconductor chip. A variety of thermal management techniques have been used ranging from passive cooling for lower power chips, to air cooling facilitated by heat sinks for medium power chips and to liquid cooling for high power chips.

The thermal management challenge has been exacerbated by recent advances in heterogeneous integration in chip and packaging level architecture. For example, bonding of multiple dies to produce three-dimensional (3D) integrated circuits offers several important electrical benefits, contributing towards continuation of Moore's law, but also leads to significant thermal contact resistance between dies, which may increase the total temperature rise in the chip. The use of dis-similar materials in different dies (heterogeneous integration, such as memory-on-logic chips) or within a single die of new structures such as back-side distribution structures and the use of 3D stacked chiplets (due to the use of through-silicon vias (TSVs) that help to enable 3D die stacks) also presents thermal management challenges from a heat source such as active circuits to a heat sink, lid or heat spreader. It is especially technically challenging to remove heat from all chips or chiplets in a 3D chip stack since the path from the heat source or multiple heat sources typically must pass through each chip in the chip stack to the heat sink.

### SUMMARY

Semiconductor structures are provided in which heat spreading and thermal heat removal are improved by providing one or more heat removal paths in which heat spreading and thermal heat removal occurs leveraging horizontal direction and vertical directions and through reduced resistance of heat removal paths. Notably, heat is spread horizontally to the edges of the semiconductor structures and then the heat is removed vertically (up and/or down) from the semiconductor structures.

In one aspect of the present application, a semiconductor structure is provided. In one embodiment, the semiconductor structure includes a front-end-of-the-line (FEOL) level including at least one semiconductor device and having a frontside and a backside, a frontside back-end-of-the-line (BEOL) structure located on the frontside of the FEOL level, a backside BEOL structure located on the backside of the FEOL level, and a heat path in which heat is spread in a horizontal direction to edges of the structure, and then the heat that is spread to the edges is removed in a vertical direction.

In another aspect of the present application, a chip stack containing structure is provided that includes at least one row of a second semiconductor chip stacked above, and bonded to, a first semiconductor chip, and a heat path in which heat is spread in a horizontal direction to edges of the at least one row of the second semiconductor chip stacked above, and bonded to, the first semiconductor chip, and then the heat that is spread to the edges is removed in a vertical direction.

In a further aspect of the present application, a structure is provided that includes a semiconductor chip electrically connected to a packaging substrate, wherein the semiconductor chip includes a heat path in which heat is spread in a horizontal direction to edges of the semiconductor chip, and then the heat that is spread to the edges is removed in a vertical direction, and a dielectric material structure laterally adjacent to, and located on top of, the semiconductor chip, wherein the dielectric material structure includes a core layer embedded therein.

### BRIEF DESCRIPTION OF THE DRAWINGS

FIG. 1 is a cross sectional view of an exemplary semiconductor structure in accordance with an embodiment of the present application.

FIG. 2 is a cross sectional view of another exemplary semiconductor structure in accordance with an embodiment of the present application.

FIG. 3 is a cross sectional view of a further exemplary semiconductor structure in accordance with an embodiment of the present application.

FIG. 4 is a cross sectional view of a yet further exemplary semiconductor structure in accordance with an embodiment of the present application.

FIG. 5 is a cross sectional view of a still further exemplary semiconductor structure in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

Despite the above benefits with backside power delivery, backside power delivery is thermally challenging. For example, and in traditional semiconductor structures including backside power delivery heat spreading and thermal heat removal typically occurs in a vertical direction from the backside of the semiconductor structure that contains a backside power delivery (i.e., a backside back-end-of-the-line (BEOL)) structure to the frontside that can include a heat sink located above a frontside BEOL structure. Such heat spreading/heat removal has a limit on the temperature maximum that can be removed due to poor heat spreading and/or limited heat removal vertically. There thus a need for providing semiconductor structures in which heating spreading and thermal heat removal is improved.

In the present application, semiconductor structures are provided in which heat spreading and thermal heat removal are improved by providing a heat path in which heat spreading and thermal heat removal occurs in both a horizontal direction and a vertical direction. Notably, heat is spread horizontally to the edges of the semiconductor structures and then the heat is removed vertically (up and/or down) from the semiconductor structures. In some embodiments, the semiconductor structure can be a component of a chip stack, a packaging substrate or an electronic module. In other embodiments, the semiconductor structure can be a component of a laminate structure.

This novel approach of heat spreading and thermal heat removal can be achieved by various means including for example, (i) increasing the density of metal structures (i.e., metal vias and/or metal lines) present in at least one of the frontside BEOL structure or backside BEOL structure to a percentage that is beyond that which is required by power delivery and/or signal delivery (typically, the density of the metal vias and/or metal lines in the frontside BEOL structure and/or backside BEOL structure is increased in the present application from less than 20% up to greater than 50% beyond that which is required by power delivery and/or signal delivery for active chip or chip stack function), and/or (ii) increasing the thermal conductivity of the frontside BEOL structure and/or backside BEOL structure to a value of greater than about 0.5 W/mK (in which W is watts, m is meter and K is Kelvin) up to as high as about 10 to 2000 W/mK by using enhanced thermally conductivity dielectric materials, and/or (iii) using metal conductors having a thermal conductivity of greater than 40 W/mK in combination with enhanced thermally conductivity dielectric materials.

These and other aspects of the present application will be described in greater detail by referring to the drawings that accompany the present application and the discussion of those drawings herein below. Before describing the drawings of the present application however, the following terms which appear throughout this application are defined.

A semiconductor structure includes a front-end-of-the-line (FEOL) level that includes one or more semiconductor devices present therein. The one or more semiconductor devices can include, for example, a transistor, a capacitor, a diode, and/or a resistor. The FEOL level can also be referred to as a semiconductor device level. In some embodiments, the FEOL level can include a semiconductor substrate including at least one semiconductor material. In other embodiments, the FEOL level can be absent of a semiconductor substrate (in such an embodiments, the semiconductor substrate can be removed during backside processing of the semiconductor structure). The semiconductor structure includes a frontside and a backside. The frontside includes a side of the structure that includes the FEOL level, an optional middle-of-the-line (MOL) level, and a frontside BEOL structure. The backside of the semiconductor structure is the side of the semiconductor structure that is opposite the frontside. The backside can include a backside BEOL structure. The semiconductor structure can include a semiconductor chip, a chiplet, or a 3D chip stack including the semiconductor chip or chiplet.

A semiconductor material is a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors.

A frontside BEOL structure is a structure that is composed of a frontside interconnect dielectric region having frontside metal wiring embedded therein. The frontside interconnect dielectric region includes one or more interconnect dielectric layers. The one or more interconnect dielectric layers are composed of an interlayer dielectric (ILD) material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that can have a dielectric constant of less than 4.0. All dielectric constants mentioned here are measured in a vacuum unless otherwise stated. Notably, the ILD materials used in providing a conventional frontside BEOL structure has a low thermal conductivity; the term “low thermal conductivity” denotes a thermal conductivity of less than 0.5 W/mK. The frontside metal wiring can be in the form of metal lines, metal vias, metal via/metal line combinations or any combinations of such conductor structures. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. Some of the frontside metal wiring can be used for signal delivery to the one or more semiconductor devices present in the FEOL level, while other frontside metal wiring can be used as a fill area.

A MOL level includes frontside contact structures embedded in a MOL dielectric region. The frontside contact structures can be composed of an electrically conductive metal or an electrically conductive metal alloy both as exemplified above. The MOL dielectric region is composed of one of more ILD materials as defined above for the frontside BEOL structure. Notably, the ILD material used in providing a conventional MOL dielectric has a low thermal conductivity, as defined above.

A backside BEOL structure is a structure that is composed of a backside interconnect dielectric region having backside metal wiring embedded therein. The backside interconnect dielectric region includes one or more interconnect dielectric layers. The one or more interconnect dielectric layers are composed of an ILD material as mentioned above for the frontside BEOL structure. Notably, the ILD materials used in providing a conventional backside BEOL structure has a low thermal conductivity, as defined above. The backside metal wiring can be in the form of metal lines, metal vias, metal via/metal line combinations or any combinations of such conductor structures. The backside metal wiring is composed of an electrically conductive metal or an electrically conductive metal alloy, both as exemplified above. The backside metal wiring of the backside BEOL structure delivers power to the one or more semiconductor devices present in the FEOL level through the backside of the semiconductor structure.

A 3D chip stack or chiplet stack is a stack including at least one semiconductor chip or chiplet stacked on top of, and bonded to, another semiconductor chip or chiplet. The chip stacking (second over the first) can include frontside to frontside, backside to backside, frontside to backside, or backside to backside.

A packaging substrate is a structure that includes a semiconductor structure as defined above, or a 3D chip stack as defined above, a packaging substrate and an electrically conductive lid. The semiconductor structure or 3D chip stack is located between the packaging substrate and the electrically conductive lid.

An electronic module includes a plurality of rows of stacked and bonded semiconductor chips or chiplets, and a packaging substrate.

A laminate structure is a structure that includes a semiconductor structure as defined above, or a 3D chip stack as defined above, a core and a heat spreader. The semiconductor structure or 3D chip stack is located between the core and the heat spreader. The core can be a ceramic core and a metal core. In a conventional laminate structure, the core can be present between an upper thermal conductive sheet and a lower thermal conductive sheet.

Reference is now made to FIGS. 1-5 which illustrate semiconductor structures in accordance with various embodiments of the present application. Each of the semiconductor structures illustrated in FIGS. 1-5 includes a heat path in which heat spreading and thermal heat removal occurs in both a horizontal direction and a vertical direction. Notably, and in FIGS. 1-5 heat is spread horizontally to the edges of the semiconductor structures and then the heat is removed vertically (up and/or down) from the semiconductor structures.

Referring first to FIG. 1, there is illustrated an exemplary semiconductor structure in accordance with an embodiment of the present application. The exemplary structure illustrated in FIG. 1 includes a FEOL level 10 including one of more semiconductor devices as mentioned above. In some embodiments, the one or more semiconductor device can be present on a surface of a semiconductor material as defined above. In other embodiments, no semiconductor material is present in the FEOL level 10. The FEOL level 10 includes a frontside and a backside. The FEOL level 10 can be formed utilizing FEOL processing techniques that are well known to those skilled in the art. For example, the FEOL level 10 can include nanosheet transistors that are formed utilizing any well-known nanosheet device formation process.

The structure shown in FIG. 1 further includes a MOL level 12 and a frontside BEOL structure 18 located on the frontside of the FEOL level 10, and a backside BEOL structure 30 located on the backside of the FEOL level 10. The MOL level 12 includes frontside contact structures 14 embedded in a MOL dielectric region 16. In some embodiments, the MOL level 12 can be omitted from the structure. In the illustrated embodiment of FIG. 1, the frontside contact structures 14 are composed of an electrically conductive material (i.e., electrically conductive metal or electrically conductive material alloy as mentioned above). In the illustrated embodiment of FIG. 1, the MOL dielectric region 16 is composed of one or more ILD materials having a low thermal conductivity, as defined above. The MOL level 12 can be formed utilizing processing techniques that are well known to those skilled in the art. For example, the MOL dielectric region 16 of the MOL level 12 can be formed by deposition of one or more ILD materials. The frontside contact structures 14 can be formed by a metallization (or damascene) process.

The frontside BEOL structure 18 which is located on the frontside of the FEOL level 10 and on top of the MOL level 12 includes frontside wiring 20 embedded in a frontside interconnect dielectric region 22. In the illustrated embodiment of FIG. 1, the frontside wiring 20 is composed of an electrically conductive material (i.e., electrically conductive metal or electrically conductive material alloy as mentioned above). In the illustrated embodiment of FIG. 1, the frontside interconnect dielectric region 22 is composed of one or more ILD materials having a low thermal conductivity, as defined above. The frontside BEOL structure 18 can be formed utilizing processing techniques that are well known in the art. Notably, the frontside interconnect dielectric region 22 of the BEOL structure 18 can be formed by deposition of one or more ILD materials. The frontside wiring 20 of the BEOL structure 18 can be formed by a metallization (or damascene) process.

The backside BEOL structure 30 includes a lower portion 30L and an upper portion 30U. The upper portion 30U of the backside BEOL structure 30 is present nearer to the FEOL level 10 than the lower portion 30L of the backside BEOL structure 30. The lower portion 30L of the backside BEOL structure 30 includes backside wiring 26 (i.e., metal structures as defined above) embedded in a backside dielectric region 28. In illustrated embodiment of FIG. 1, the backside wiring 26 can be composed of an electrically conductive material (i.e., electrically conductive metal or electrically conductive material alloy as mentioned above). In some embodiments, the backside wiring 26 present in the upper portion 30U of the backside BEOL structure 30 can be composed of an electrically conductive material having a thermal conductivity of greater than 40 W/mK. Illustrative examples of such thermally conductive conductors include, but are not limited to, Cu, Al, Ta, Mo, W, CuMo, Sn, solder, Ag, Au or alloys thereof. Note that some of backside wiring 26 include portions that extend laterally to the edge of the backside dielectric region 28. This facilitates spreading the heat in a horizontal direct from the exterior of the upper portion 30U of the backside BEOL structure 30 to the edges of the upper portion 30U of the backside BEOL structure 30.

In some embodiments, the density of the backside wiring 26 is within limits for traditional backside power delivery that supports product function while limiting the excessive total metal required beyond base product function due to potential decreases in product yield with excessive metal loading. In other embodiments, the density of the backside wiring 26 is beyond limits for traditional backside power delivery. In some embodiments in which the density of the backside wiring 26 is beyond limits for traditional backside power delivery, the additional density of the backside wiring 26 can be used for heat spreading and heat removal from the exemplary structure. In some embodiments in which the density of the backside wiring 26 is beyond limits for traditional backside power delivery for chip of chiplet function, the additional density of the backside wiring 26 may be from 10% to over 50% metal loading above that required for chip function. The increased density of backside wiring 26 can be used to improve the heat spreading and heat removal of the structure and thereby help to reduce chip operating temperature which can improve chip reliability and product life.

In the illustrated embodiment, the backside dielectric region 28 is composed of one or more ILD materials having a thermal conductivity of greater than 0.5 W/mK up to 2000 W/mK (in some embodiment the thermal conductivity is greater than 10 W/mK up to 2000 W/mK) pending structure for chiplet and advanced packaging elements. In some embodiments, the one or more ILD materials that provide the backside dielectric region 28 has a thermal conductivity from greater than 1 W/mK to 10 W/mK. In such embodiments, the one or more ILD materials have a layer thickness of greater than 1 micron to 40 microns or greater. Exemplary ILD materials that have a thermal conductivity from greater than 1 W/mK to 10 W/mK include, but are not limited to, silicon dioxide, SIN, SiCN, SiOCN, Al₂O₃ or glass. In further embodiments, the one or more ILD materials that provide the backside dielectric region 28 has a thermal conductivity from greater than 10 W/mK to 500 W/mK. In such embodiments, the one or more ILD materials have a layer thickness of greater than 0.1 micron to 10 microns or greater. Exemplary ILD materials that have a thermal conductivity from greater than 10 W/mK to 500 W/mK include, but are not limited to, AlN, BeO, sapphire or diamond-like carbon. The use of the aforementioned “high thermal conductivity” ILD materials (the term “high thermal conductivity” denotes a ILD material that has a thermal conductivity of greater than 1 W/mK, typically greater than 10 W/mK) can provide improved heat spreading and heat removal to the structure illustrated in FIG. 1. In the illustrated embodiment, the entire backside dielectric region 28 can be composed of high thermal conductivity ILD materials. In other embodiments, at least one portion (or at least one ILD layer) of the backside dielectric region 28 is composed of a high thermal conductivity ILD material, while other portions (including at least one or more of the ILD layers) of the backside dielectric region 28 can be composed of low thermal conductivity ILD material. The use of high thermal conductivity ILD materials for the backside dielectric region 28 can be used in conjunction with the use of high thermal conductivity conductors, and/or the increased density of backside wiring 26. In other embodiments, the entire backside dielectric region 28 can be composed of low thermal conducive ILD materials and in such embodiments the heat spreading and heat removal can be improved the use of high thermal conductivity conductors, and/or the increased density of backside wiring 26.

The lower portion 30L of the backside BEOL structure 30 includes a backside power region 32 and backside interconnect structures 33 embedded in a backside interconnect dielectric region 34. The backside BEOL structure 30 can be formed utilizing processing techniques well known to those skilled in the art. The backside power region 32 is an input/output interconnection region. In illustrated embodiment of FIG. 1, the backside power region 32 and backside interconnect structures 33 can be composed of an electrically conductive material (i.e., electrically conductive metal or electrically conductive material alloy as mentioned above). In some embodiments, backside power region 32 and the backside interconnect structures 33 present in the backside BEOL structure 30 can be composed of an electrically conductive material such as, but not limited to, Cu having a thermal conductivity of greater than 40 W/mK.

In the illustrated embodiment, the backside interconnect dielectric region 34 is composed of one or more ILD materials having a thermal conductivity of greater than 0.5 W/mK up to 2000 W/mK. In some embodiments, the one or more ILD materials that provide the backside interconnect dielectric region 34 has a thermal conductivity from greater than 1 W/mK to 10 W/mK. In such embodiments, the one or more ILD materials have a layer thickness of greater than 1 micron to 40 microns or greater. In further embodiments, the one or more ILD materials that provide the backside interconnect dielectric region 34 has a thermal conductivity from greater than 10 W/mK to 500 W/mK. In such embodiments, the one or more ILD materials have a layer thickness of greater than 0.1 micron to 10 microns or greater The use of the aforementioned “high thermal conductivity” ILD materials (the term “high thermal conductivity” denotes a ILD material that has a thermal conductivity of greater than 1 W·mK) can provide improved heat spreading and heat removal to the semiconductor structure illustrated in FIG. 1. In the illustrated embodiment, the entire backside interconnect dielectric region 34 can be composed of high thermal conductivity ILD materials. In other embodiments, at one portion of the backside interconnect dielectric region 34 is composed of high thermal conductivity ILD material, while other portions (including at least one or more of the ILD layers) of the backside interconnect dielectric region 34 can be composed of low thermal conductivity ILD material. The use of using high thermal conductivity ILD materials for the backside interconnect dielectric region 34 can be used in conjunction with the use of high thermal conductivity conductors for the backside power region 32 and the backside interconnect structures 33. In other embodiments, the entire backside interconnect region 34 can be composed of low thermal conducive ILD materials and in such embodiments the heat spreading and heat removal can be improved the use of high thermal conductivity conductor materials for the backside power region 32 and the backside interconnect structures 33.

In the illustrated embodiment of FIG. 1, the improved heat spreading and heat removal of the backside BEOL structure 30 provides a heat path in which heat is spread horizontally from the interior of the semiconductor structure to the edges of the structure and then the heat at the edges is removed vertically (up and/or down). Notably, and in this example, the exemplary structure has heat spreading and heat removal paths that remove heat from the FEOL level 10. The heating spreading and heat removal paths include using the increased electrical conductors such as via stacks and/or increased dielectric thermal conductivity where heat spreading and heat removal paths can be from the FEOL level 10 to the top of the chiplet stack to the heat spreader and/or down from the FEOL level 10 through increased electrical conductors and increased dielectric thermal conduction materials where heat can subsequently be transported to a heat spreader, thermal conductors and subsequently to lids or heat sinks at the perimeter of the chip stack and up to a heat sink layer to the heat sink and vertically to the heat sink. Although not illustrated in FIG. 1, the MOL level 12 and/or the frontside BEOL structure 18 can be designed to have the improved heat spreading and heat removal as the backside BEOL structure 30, respectively. In embodiments in which a backside BEOL structure 30 is not present, the MOL level 12 and/or the frontside BEOL structure 18 can be designed to have the improved heat spreading and heat removal as the backside BEOL structure 30.

Notably, FIG. 1 illustrates a semiconductor structure in accordance with an embodiment of the present application. The illustrated semiconductor structure of FIG. 1 includes FEOL 10 level including at least one semiconductor device and having a frontside and a backside, frontside BEOL structure 18 located on the frontside of the FEOL level 10, backside BEOL structure 30 located on the backside of the FEOL level 10, and a heat path in which heat is spread in a horizontal direction to edges of the structure, and then the heat that is spread to the edges is removed in a vertical direction. In this embodiment, the improved heat spreading and heat removal is provided in the backside BEOL structure 30. The improved heat spreading and heat removal can be in any of, or any combination of, the frontside BEOL structure 18, the MOL level 12 and the backside BEOL structure 30. Best results are observed when the improved heat spreading and thermal removal is present in each of the frontside BEOL structure 18, the MOL level 12, and the backside BEOL structure 30.

In some embodiments, the heat path present in FIG. 1 includes (i) an increase of metal structures present in at least one of the frontside BEOL structure 18 or the backside BEOL structure 30 to a percentage beyond that which is required by power delivery or signal delivery, (ii) ILD materials in at least one of the frontside BEOL structure 18 or the backside BEOL 30 having a thermal conductivity greater than 0.5 W/mK up to 2000 W/mK, or (iii) metal conductors present in at least one of the frontside BEOL structure 18 or the backside BEOL structure 30 that have a thermal conductivity of greater than 40 W/mK in combination with ILD materials in at least one of the frontside BEOL structure or the backside BEOL that have a thermal conductivity greater than 0.5 W/mK up to 2000 W/mK, or any combination thereof.

In some embodiments, the heat path includes (i) above, and the percentage of metal structures present in at least one of the frontside BEOL structure 18 or the backside BEOL structure can be increased by 10% to greater than 50% higher than base circuit function.

In some embodiments, the heat path comprises (ii) or (iii) above, and the thermal conductivity of the ILD materials is from greater than 1 W/mK to 10 W/mK.

In some embodiments, the heat path comprises (ii) or (iii) above, and the thermal conductivity of the ILD materials is from greater than 10 W/mK to 500 W/mK.

In some embodiments of the present application, at least a first set of metal structures present in at least one of the frontside BEOL structure 18 or the backside BEOL structure 30 extend laterally to an edge of frontside BEOL structure 18 or the backside BEOL structure 30. This aspect facilities lateral heat spreading.

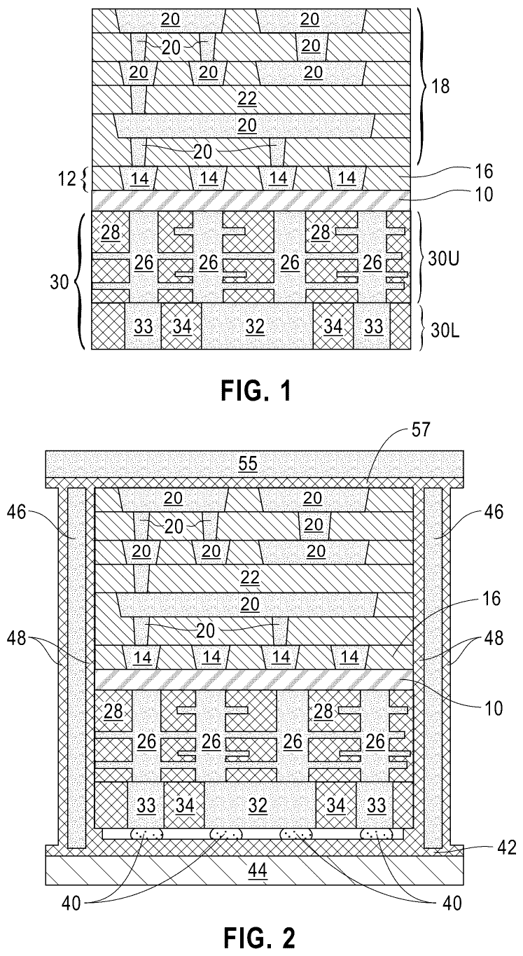

Referring now to FIG. 2, there is illustrated another exemplary semiconductor structure in accordance with an embodiment of the present application. The exemplary semiconductor structure shown in FIG. 2 includes FEOL level 10, MOL level 12, frontside BEOL structure 18, and backside BEOL structure 30 illustrated in FIG. 1. In the illustrated structure shown in FIG. 2, solder balls 40 are located on a surface of the backside BEOL structure 30 and the solder balls 40 are used to electrically connect the backside BEOL structure 30 to a packaging substrate 44. The electrically connection can be through a first thermal insulating material 42 that is located on surface of the packaging substrate 44.

The solder balls 40 are composed of conventional solder ball materials including lead or lead-free solder balls that are well known to those skilled in the art. In some embodiments, the first thermal insulating material (TIM) 42 can be composed of a conventional material that is well known to those skilled in the art. In other embodiments, the first thermal insulating material 42 is composed of a high thermal conductivity ILD material as defined above. The packaging substrate 44 can be composed of any conventional packaging material including an organic laminated substrate that is well known to those skilled in the art. In embodiments of the present application, an underfill material layer (not shown) can be used to encase each of the solder balls 40 and to fill in any gap that is located between the backside BEOL structure 30 and the first thermal insulating material 42 that is present on the packaging substrate 44. The attachment of the backside BEOL structure 30 to the packaging substrate can be performed utilizing techniques well known to those skilled in the art in which solder is used as a means of attachment.

FIG. 2 also show through via structures 46 that extend from the topmost surface of the frontside BEOL structure 18 to the first thermal insulating material 42 that is present on the packaging substrate 44. The through via structures 46 are present in a through via dielectric region 48. The through via structures 46 can be composed of one or more electrically connected vias that extend entirely through the through via dielectric region 48. The through via structures 46 can be composed of an electrically conductive material (i.e., electrically conductive metal or electrically conductive material alloy as mentioned above). In some embodiments, the through via structures 46 can be composed of an electrically conductive material having a thermal conductivity of greater than 40 W/mK, as illustrated above. In some embodiments, the through via dielectric region 48 is composed of one or more ILD materials having a thermal conductivity of greater than 0.5 W/mK up to 2000 W/mK. In some embodiments, the one or more ILD materials that provide the through via dielectric region 48 has a thermal conductivity from greater than 1 W/mK to 10 W/mK. In further embodiments, the one or more ILD materials that provide the through via dielectric region 48 has a thermal conductivity from greater than 10 W/mK to 500 W/mK. The use of the aforementioned “high thermal conductivity” ILD materials can provide improved heat removal to the semiconductor structure illustrated in FIG. 2. In other embodiments, at one portion of the through via dielectric region 48 is composed of high thermal conductivity ILD materials, while other portions (including at least one or more of the ILD layers) of the through via dielectric region 48 can be composed of low thermal conductivity ILD materials. The use of high thermal conductivity ILD materials for the through via dielectric region 48 can be used in conjunction with the use of high thermal conductivity conductors as the through via structures 46. In other embodiments, the entire through via dielectric region 48 can be composed of low thermal conducive ILD materials and in such embodiments the heat removal can be improved by the use of high thermal conductivity conductors as the through via structures 44. The through via structures 46 and the through via dielectric region 48 can be formed utilizing techniques well known to those skilled in the art.

FIG. 2 also shows a lid 55 that is formed on top of the frontside BEOL structure 18. In some embodiments, a second thermal insulating material 57 is present between the lid 55 and the frontside BEOL structure 18. The second thermal insulating material 57 and the lid 55 extend above the through via dielectric region 48 that contains the through via structures 46. Lid 55 is composed of an electrically conductive material such as, for example, Cu. In some embodiments, the second thermal insulating material 57 can be composed a conventional material that is well known to those skilled in the art. In other embodiments, the second thermal insulating material 57 is composed of a high thermal conductivity ILD material as defined above.

The exemplary structure illustrated in FIG. 2 is a packaging structure including the semiconductor structure shown in FIG. 1. The semiconductor structure can be diced into a chip or chiplet prior to use in the exemplary structure shown in FIG. 2. The exemplary structure shown in FIG. 2 provides a heat path in which heat is spread horizontally from the interior of the semiconductor structure to the edges of the structure and then the heat at the edges is removed vertically (up and/or down). In this example, the exemplary structure has heat spreading and heat removal paths that remove heat from the FEOL level 10. The heat spreading and heat removal paths include (1) device level horizontally and up vertically through electrical conduction paths of wiring and via stacks to the thermal insulating material (TIM) or high thermal conductivity layer and the top heat sink and vertical heat removal from the FEOL level 10 to the heat sink through dielectric layers to the TIM or high thermal conductivity layer to the heat sink, (2) device horizontally and down through electrical conduction paths of wiring and via stacks to the bottom of stack and interconnections, then horizontally through high thermal conductivity layer and conductor layers to edge of chiplet stack and then to the TIM or high thermal conductivity layer upward through side heat transport lid and/or thermal conduction paths to top heat sink, and/or (3) from device layer through electrical conductors, wires and vias/via stacks and dielectric materials above and below device layer and horizontally to sides of chiplet stack through to the TIM or high thermal conductivity layer to heat sink and vertically to heat sink. Although not illustrated in FIG. 2, the MOL level 12 and/or the frontside BEOL structure 18 can be designed to have the improved heat spreading and heat removal as the backside BEOL structure 30. In the illustrated embodiment of FIG. 2, the improved heat spreading and heat removal is provided in the backside BEOL structure 30. The improved heat spreading and heat removal can be in any of, or any combination of, the frontside BEOL structure 18, the MOL level 12 and the backside BEOL structure 30. Best results are observed when the improved heat spreading and thermal removal is present in each of the frontside BEOL structure 18, the MOL level 12, and the backside BEOL structure 30.

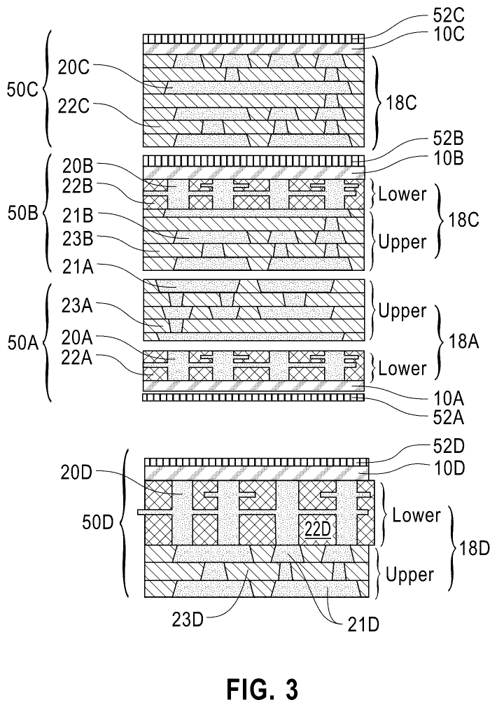

Referring now to FIG. 3, there is illustrated a further exemplary semiconductor structure in accordance with an embodiment of the present application. The exemplary semiconductor structure shown in FIG. 3 is a 3D chip stack (or chiplet stack) which includes three semiconductor structures 50A, 50B, 50C stacked one on top of the other; a fourth semiconductor structure 50D is also shown which will be bonded to the first semiconductor structure 50A of the already bonded 3D chip stack. The first semiconductor structure 50A includes a first semiconductor substrate 52A, a first semiconductor structure FEOL level 10A and a first frontside BEOL structure 18A. The first semiconductor substrate 10A includes one of the semiconductor materials mentioned above. The first frontside BEOL structure 18A includes a lower portion having lower frontside metal wiring 20A embedded in a lower frontside interconnect dielectric region 22A. In the illustrated embodiment of FIG. 3, some of the lower frontside metal wiring 20A extends to the edges of the lower frontside interconnect dielectric region 22A. The lower frontside wiring 20A can be composed of an electrically conductive material (i.e., electrically conductive metal or electrically conductive material alloy as mentioned above). In some embodiments, the lower frontside metal wiring 20A can be composed of a high thermal conductivity conductors and/or there can an increased density of lower frontside metal wiring 20A present in the lower frontside interconnect dielectric region 22A. The lower frontside interconnect dielectric region 22A is composed of one or more ILD materials that have a high thermal conductivity as defined above. The first frontside BEOL structure 18A also includes an upper portion that includes upper frontside metal wiring 21A embedded in an upper frontside interconnect dielectric region 23A. The upper frontside metal wiring 21A is composed of an electrically conductive metal or electrically conductive metal alloy as defined above, while the upper frontside interconnect dielectric region 23A is composed of at least one ILD material that is found in conventional frontside BEOL structures. Note it is possible to design the upper portion of the first frontside BEOL structure 18A to have improved heat spreading and heat removal as provided by the lower portion of the first frontside BEOL structure 18A.

The second semiconductor structure 50B includes a second semiconductor substrate 52B, a second FEOL level 10B and a second frontside BEOL structure 18B. The second semiconductor substrate 50B includes a semiconductor material as mentioned above. The second frontside BEOL structure 18B is hybrid bonded to the first frontside BEOL structure 18A. In hybrid bonding, a hybrid bonding interface, HBI, is formed that includes dielectric-to-dielectric bonds and metal-to-metal bonds. The second frontside BEOL structure 18B includes a lower portion that includes lower frontside metal wiring 20B embedded in a lower frontside interconnect dielectric region 22B. In the illustrated embodiment of FIG. 3, some of the lower frontside metal wiring 20B extends to the edges of the lower frontside interconnect dielectric region 22B. The lower frontside wiring 20B can be composed of an electrically conductive material (i.e., electrically conductive metal or electrically conductive material alloy as mentioned above). In some embodiments, the lower frontside wiring 20B can be composed of a high thermal conductivity conductors and/or there can an increased density of lower frontside metal wiring 20B present in the lower frontside interconnect dielectric region 22B. The lower frontside interconnect dielectric region 22B is composed of one or more ILD materials that have a high thermal conductivity as defined above. The second frontside BEOL structure 18B also includes an upper portion that includes upper frontside metal wiring 21B embedded in an upper frontside interconnect dielectric region 23B. The upper frontside metal wiring 21B is composed of an electrically conductive metal or electrically conductive metal alloy as defined above, while the upper frontside interconnect dielectric region 23B is composed of at least one ILD material that is found in conventional frontside BEOL structures. Note it is possible to design the upper portion of the second frontside BEOL structure 18B to have improved heat spreading and heat removal as provided by the lower portion of the second frontside BEOL structure 18B.

In the illustrated embodiment, the second semiconductor substrate 10B of the second semiconductor structure 50B is bonded to a frontside BEOL structure 18C of a third semiconductor structure 50C, which also includes a third FEOL level 10C and a third semiconductor substrate 52C. The third semiconductor substrate 50C includes a semiconductor material as mentioned above. The third BEOL structure 18C of the third semiconductor structure 50C includes third frontside metal wiring 20C embedded in a third frontside interconnect dielectric region 22C. The third frontside metal wiring 20C is composed of an electrically conductive metal or electrically contact metal alloy as mentioned above for the frontside BEOL structure 18 illustrated in FIG. 1. The third frontside interconnect dielectric region 22C is composed of one or more ILD materials as mentioned above for the frontside interconnect dielectric region 22 illustrated in FIG. 1. Although not shown, the third frontside BEOL structure 18C can be designed to have improved heat spreading and heat removal as provided herein.

The fourth semiconductor structure 50D includes a fourth semiconductor substrate 52D, a fourth FEOL level 10D, and fourth frontside BEOL structure 18D. The fourth semiconductor substrate 52D will be bonded to the first semiconductor substrate 52A of the first semiconductor structure 50A. The fourth semiconductor substrate 50D includes a semiconductor material as mentioned above. The fourth frontside BEOL structure 18D includes a lower portion that includes lower frontside metal wiring 20D embedded in a lower frontside interconnect dielectric region 22D. In the illustrated embodiment of FIG. 3, some of the lower frontside metal wiring 20D extends to the edges of the lower frontside interconnect dielectric region 22D. The lower frontside wiring 20D can be composed of an electrically conductive material (i.e., electrically conductive metal or electrically conductive material alloy as mentioned above). In some embodiments, the lower frontside wiring 20D can be composed of a high thermal conductivity conductors and/or there can an increased density of lower frontside metal wiring 20D present in the lower frontside interconnect dielectric region 22D. The lower frontside interconnect dielectric region 22D is composed of one or more ILD materials that have a high thermal conductivity as defined above. The fourth frontside BEOL structure 18D also includes an upper portion that includes upper frontside metal wiring 21D embedded in an upper frontside interconnect dielectric region 23D. The upper frontside metal wiring 21D is composed of an electrically conductive metal or electrically conductive metal alloy as defined above, while the upper frontside interconnect dielectric region 23D is composed of at least one ILD material that is found in conventional frontside BEOL structures. Note it is possible to design the upper portion of the fourth frontside BEOL structure 18D to have improved heat spreading and heat removal as provided by the lower portion of the fourth frontside BEOL structure 18D.

The exemplary structure shown in FIG. 3 provides a heat path in which heat is spread horizontally from the interior of the semiconductor structure to the edges of the structure and then the heat at the edges is removed vertically (up and/or down). The heat spreading and thermal heat removal path for FIG. 3 can utilize the same spreading paths as described above for FIGS. 1 and 2 using one or more stack chiplet stack layers and utilized an additional horizontal heat spreading path and layers between segments of chiplet stacks that can aide in heat removal above and below each chiplet stack layers horizontally to heat sinks at edge of chiplet stacks and up to a heat sink.

Notably, FIG. 3 provides a chip stack containing structure in accordance with an embodiment of the present application. The chip stack containing structure includes at least one row of a second semiconductor chip (i.e., second semiconductor structure 50B) stacked above, and bonded to, a first semiconductor chip (i.e., first semiconductor structure 50A), and a heat path in which heat is spread in a horizontal direction to edges of the at least one row of the second semiconductor chip stacked above, and bonded to, the first semiconductor chip, and then the heat that is spread to the edges is removed in a vertical direction.

In embodiments, the heat path present in the chip stack containing structures includes (i) an increase of metal structures present at least one of the first semiconductor chip or the second semiconductor chip to a percentage that is beyond that which is required by power delivery or signal delivery, (ii) ILD materials in the first semiconductor chip or the second semiconductor chip that have a thermal conductivity greater than 0.5 W/mK up to 2000 W/mK, or (iii) metal conductors present in the first semiconductor chip or the second semiconductor chip that have a thermal conductivity of greater than 40 W/mK in combination with ILD materials in the first semiconductor chip or the second semiconductor chip that have a thermal conductivity greater than 0.5 W/mK up to 2000 W/mK, or any combination thereof.

In some embodiments, the heat path present in the chip stack containing structure includes (i) above, and the percentage of metal structures present in at least one of the first semiconductor chip or the second semiconductor chip is from 10% to greater than 50% above level for standard chiplet function.

In some embodiments, the heat path present in the chip stack containing structure includes (ii) or (iii) above, and the thermal conductivity of the ILD materials is from greater than 1 W/mK to 10 W/mK.

In some embodiments, the heat path present in the chip stack containing structure includes (ii) or (iii) above, and the thermal conductivity of the ILD materials is from greater than 10 W/mK to 500 W/mK.

In some embodiments, the metal structures present in at least one of the first semiconductor chip or the second semiconductor chip extend laterally to an edge of the first semiconductor chip or the second semiconductor chip. The facilities horizontal heat spreading.

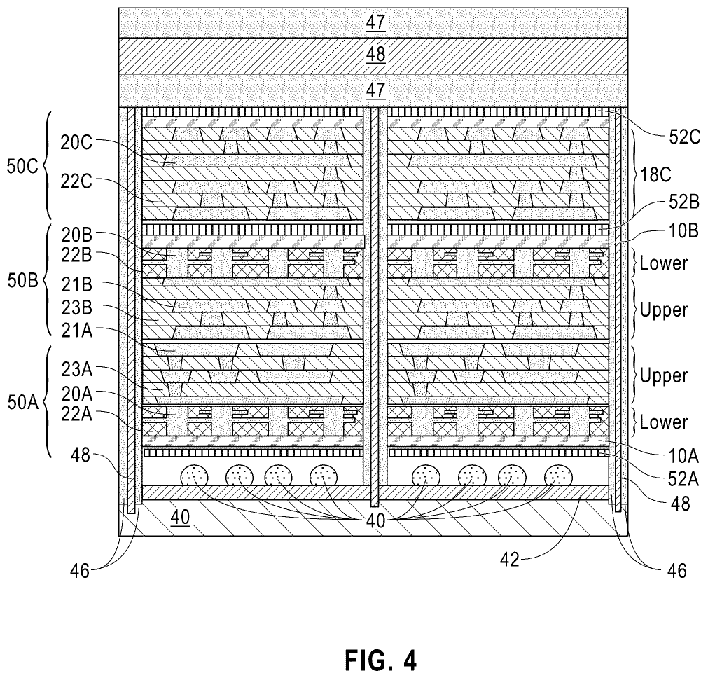

In some embodiments as will be apparent from FIG. 4, the chip stack containing structure can include packaging substrate 44 electrically connected to the first semiconductor chip, through via structure 46 embedded in a through via dielectric region 48 and extending vertically from the first semiconductor chip to the second semiconductor chip and a horizontal through via structure 47 located on top of the at least one of the second semiconductor chip stacked above, and bonded to, the first semiconductor chip.

Referring now to FIG. 4, there is illustrated a yet further exemplary semiconductor structure in accordance with an embodiment of the present application. Notably, the exemplary semiconductor structure illustrated FIG. 4 is an electronic module including a first row of stacked and bonded semiconductor chips and a second row of sacked and bonded semiconductor chips that are spaced apart from the first row. The first and second rows of stacked and bonded semiconductor chips each includes three semiconductor structures 50A, 50B, 50C stacked one on top of the other. The three semiconductor structures 50A, 50B, 50C used in FIG. 4 are the same as the three semiconductor structures 50A, 50B, 50C shown in FIG. 3. Thus, the components/elements that provide the three semiconductor structures 50A, 50B, 50C mentioned above in regard to FIG. 3 apply here for the three semiconductor structures 50A, 50B, 50C.

The exemplary semiconductor structure of FIG. 4 also includes solder balls 40 (as described above in regard to FIG. 2) that are used to electrically connect the first semiconductor substrate 52A to packaging substrate 44 (as also described above in regard to FIG. 2). The electrically connection can be through first thermal insulating material 42 (as further described above in regard to FIG. 2) that is located on surface of the packaging substrate 44.

In embodiments of the present application, an underfill material layer (not shown) can be used to encase each of the solder balls 40 and to fill in any gap that is located between the first semiconductor substrate 52A and the first thermal insulating material 42 that is present on the packaging substrate 44. The attachment each row of stacked semiconductor chips to the packaging substrate 44 can be performed utilizing techniques well known to those skilled in the art in which solder is used as a means of attachment.

FIG. 4 also shows through via structures 46 that extend vertically from the topmost surface of the frontside BEOL structure 18 to the packaging substrate 44. The through via structures 46 are present in a through via dielectric region 48. The through via structures 46 and through via dielectric region 48 include materials and are formed as described above with respect to FIG. 2.

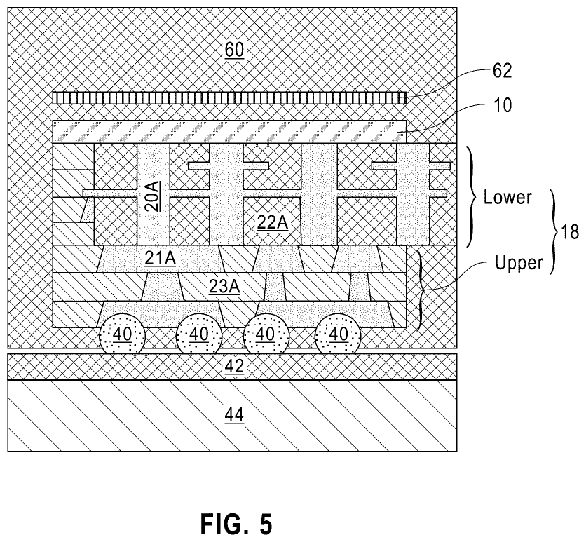

FIG. 4 further shows a horizontal through via structures 47 that are located atop the first and second rows of stacked and bonded semiconductor chips. The horizontal through via structures 47 extended from one edge to the other edge of the semiconductor structure illustrated in FIG. 5 and are separated by through via dielectric region 48. The horizontal through via structures 47 are composed of a same or different electrically conductive material as the through via structures 46. In the present application, a bottommost horizontal through via structure is attached to the third semiconductor substrate 52C of the stacked and bonded semiconductor chips of the first and second rows of sacked and bonded semiconductor chips.

The exemplary structure shown in FIG. 4 provides a heat path in which heat is spread horizontally from the interior of the stacked and bonded semiconductor chips to the edges of the stacked and bonded semiconductor chips and then the heat at the edges is removed vertically (up and/or down). The heat spreading and heat removal paths for FIG. 4 include those paths described for FIG. 3 and also include those of added vertical and horizontal heat removal paths between multiple chiplet stacks and above and below multiple chiplet stacks as would be apparent from the illustrated figures.

Referring now to FIG. 5, there is illustrated a still further exemplary semiconductor structure in accordance with an embodiment of the present application. Notably, the exemplary semiconductor structure illustrated FIG. 5 is a semiconductor chip including a FEOL 10, and a frontside BEOL structure 18 that is bonded to packaging substrate 44 (as described above in regard to FIG. 2) via solder balls 40 (as described above in regard to FIG. 2). A thermal insulating material 42 (as described above in regard to FIG. 2 can be located between the solder balls 40 and the packaging substrate 44. In this embodiment, the frontside BEOL structure 18 includes a lower portion having lower frontside metal wiring 20A embedded in a lower frontside interconnect dielectric region 22A. The lower frontside wiring 20A can be composed of an electrically conductive material (i.e., electrically conductive metal or electrically conductive material alloy as mentioned above). In some embodiments, the lower frontside metal wiring 20A can be composed of a high thermal conductivity conductors and/or there can an increased density of lower frontside metal wiring 20A present in the lower frontside interconnect dielectric region 22A. The lower frontside interconnect dielectric region 22A is composed of one or more ILD materials that have a high thermal conductivity as defined above. The frontside BEOL structure 18 also includes an upper portion that includes upper frontside metal wiring 21A embedded in an upper frontside interconnect dielectric region 23A. The upper frontside metal wiring 21A is composed of an electrically conductive metal or electrically conductive metal alloy as defined above, while the upper frontside interconnect dielectric region 23A is composed of at least one ILD material that is found in conventional frontside BEOL structures.

The FEOL level 10, the frontside BEOL structure 18 and the solder balls 40 are encased in a dielectric material structure 60. The dielectric material structure 60 includes a plurality of ILD layers that are composed of one or more ILD materials having a high thermal conductivity as defined above. The dielectric material structure 60 also include a core layer 62 embedded above the FEOL level 10. The core layer 62 is composed of heat spreader material such as, for example, one of the high thermal conductivity conductors mentioned above. The semiconductor structure can be formed by first forming the frontside BEOL structure 18 on a FEOL level 10, attaching this structure to the packaging substrate 44 via solder balls 40, and thereafter forming the dielectric material structure 60 including core layer 62.

The exemplary structure shown in FIG. 5 provides a heat path in which heat is spread horizontally from the interior of the stacked and bonded semiconductor chips to the edges of the stacked and bonded semiconductor chips and then the heat at the edges is removed vertically (up and/or down). Heat spreading and heat removal paths for FIG. 5 can be similar to FIGS. 1 and 2 and include all sides of heat removal from device to heat spreaders or heat sinks on all faces of the chiplet stack cube. Again these heat removal paths can take advantage of thermal spreading and heat removal through electrical/thermal conductors and dielectric thermal conductors and benefit from enhancements in vertical via stacks, horizontal wires and enhanced dielectric thermal conductivity enhancements and lower thermal resistance form devices to heat sinks.

Notably, FIG. 5 illustrates a semiconductor structure including a semiconductor chip electrically connected to packaging substrate 44, in which the semiconductor chip includes a heat path in which heat is spread in a horizontal direction to edges of the semiconductor chip, and then the heat that is spread to the edges is removed in a vertical direction, and a dielectric material structure laterally adjacent to, and located on top of, the semiconductor chip, wherein the dielectric material structure includes a core layer embedded therein.

In embodiments, the heat path in the structure illustrated in FIG. 5 is provided by (i) an increase of metal structures present at the semiconductor chip to a percentage that is beyond that which is required by power delivery or signal delivery, (ii) ILD materials in the semiconductor that have a thermal conductivity greater than 0.5 W/mK up to 2000 W/mK, or (iii) metal conductors present in the semiconductor chip that have a thermal conductivity of greater than 40 w/MK in combination with ILD materials in the semiconductor chip that have a thermal conductivity greater than 0.5 W/mK up to 2000 W/mK, or any combination thereof.

In some embodiments, the heat path present in the structure of FIG. 5 includes (i) above, and the percentage of metal structures present in the semiconductor chip beyond standard chip function due to increase electrical conductor structures that also serve as thermal conduction paths such as power and ground vias stacks and wires (i.e., from 10% to greater than 50% above level for standard function).

In some embodiments, the heat path present in the structure of FIG. 5 includes (ii) or (iii) above, and the thermal conductivity of the ILD materials is from greater than 1 W/mK to 10 W/mK.

In some embodiments, the heat path present in the structure of FIG. 5 includes (ii) or (iii) above, and the thermal conductivity of the ILD materials is from greater than 10 W/mK to 500 W/mK.

In some embodiments, the structure of FIG. 5 includes a first set of metal structures present in the semiconductor chip that extend laterally to an edge of the semiconductor chip.

In any of the semiconductor structures illustrated in the present application a heat sink can be present above and/or below the exemplified structure. The heat sink can be liquid cooled or air cooled

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a front-end-of-the-line (FEOL) level comprising at least one semiconductor device and having a frontside and a backside;
a frontside back-end-of-the-line (BEOL) structure located on the frontside of the FEOL level;
a backside BEOL structure located on the frontside of the FEOL level; and
a heat path in which heat is spread in a horizontal direction to edges of the structure, and then the heat that is spread to the edges is removed in a vertical direction.

2. The semiconductor structure of claim 1, wherein the heat path comprises (i) an increase of metal structures present in at least one of the frontside BEOL structure or the backside BEOL structure to a percentage that is beyond that which is required by power delivery or signal delivery, (ii) ILD materials in at least one of the frontside BEOL structure or the backside BEOL that have a thermal conductivity greater than 0.5 W/mK up to 2000 W/mK, or (iii) metal conductors present in at least one of the frontside BEOL structure or the backside BEOL structure that have a thermal conductivity of greater than 40 w/MK in combination with ILD materials in at least one of the frontside BEOL structure or the backside BEOL that have a thermal conductivity greater than 0.5 W/mK up to 2000 W/mK, or any combination thereof.

3. The semiconductor structure of claim 2, wherein the heat path comprises (i) and the percentage of metal structures present in at least one of the frontside BEOL structure or the backside BEOL structure is from 10% to greater than 50% of level needed for chiplet or chiplet stack function.

4. The semiconductor structure of claim 2, wherein the heat path comprises (ii) or (iii) and the thermal conductivity of the ILD materials is from greater than 1 W/mK to 10 W/mK.

5. The semiconductor structure of claim 2, wherein the heat path comprises (ii) or (iii) and the thermal conductivity of the ILD materials is from greater than 10 W/mK to 500 W/mK.

6. The semiconductor structure of claim 2, wherein at least a first set of metal structures present in at least one of the frontside BEOL structure or the backside BEOL structure extend laterally to an edge of frontside BEOL structure or the backside BEOL structure.

7. The semiconductor structure of claim 1, further comprising a packaging substrate electrically connected to the backside BEOL structure, a lid attached to the frontside BEOL structure, and a through via structure embedded in a through via dielectric region and extending from the backside BEOL structure to the frontside BEOL structure.

8. A chip stack containing structure comprising:
at least one row of a second semiconductor chip stacked above, and bonded to, a first semiconductor chip; and
a heat path in which heat is spread in a horizontal direction to edges of the at least one row of comprising the second semiconductor chip stacked above, and bonded to, the first semiconductor chip, and then the heat that is spread to the edges is removed in a vertical direction.

9. The chip stack containing structure of claim 8, wherein the heat path comprises (i) an increase of metal structures present at least one of the first semiconductor chip or the second semiconductor chip to a percentage that is beyond that which is required by power delivery or signal delivery, (ii) ILD materials in the first semiconductor chip or the second semiconductor chip that have a thermal conductivity greater than 0.5 W/mK up to 2000 W/mK, or (iii) metal conductors present in the first semiconductor chip or the second semiconductor chip that have a thermal conductivity of greater than 40 w/MK in combination with ILD materials in the first semiconductor chip or the second semiconductor chip that have a thermal conductivity greater than 0.5 W/mK up to 2000 W/mK, or any combination thereof.

10. The chip stack containing structure of claim 9, wherein the heat path comprises (i) and the percentage of metal structures present in at least one of the first semiconductor chip or the second semiconductor chip is from 10% to greater than 50% of level needed for chiplet or chiplet stack function.

11. The chip stack containing structure of claim 9, wherein the heat path comprises (ii) or (iii) and the thermal conductivity of the ILD materials is from greater than 1 W/mK to 10 W/mK.

12. The chip stack containing structure of claim 9, wherein the heat path comprises (ii) or (iii) and the thermal conductivity of the ILD materials is from greater than 10 W/mK to 500 W/mK.

13. The chip stack containing structure of claim 9, wherein a first set of metal structures present in at least one of the first semiconductor chip or the second semiconductor chip extends laterally to an edge of the first semiconductor chip or the second semiconductor chip.

14. The chip stack containing structure of claim 8, further comprising a packaging substrate electrically connected to the first semiconductor chip, a through via structure embedded in a through via dielectric region and extending vertically from the first semiconductor chip to the second semiconductor chip and a horizontal through via structure located on top of the at least one of the second semiconductor chip stacked above, and bonded to, the first semiconductor chip.

15. A structure comprising:
a semiconductor chip electrically connected to a packaging substrate, wherein the semiconductor chip comprises a heat path in which heat is spread in a horizontal direction to edges of the semiconductor chip, and then the heat that is spread to the edges is removed in a vertical direction; and
a dielectric material structure laterally adjacent to, and located on top of, the semiconductor chip, wherein the dielectric material structure comprises a core layer embedded therein.

16. The structure of claim 15, wherein the heat path comprises (i) an increase of metal structures present at the semiconductor chip to a percentage that is beyond that which is required by power delivery or signal delivery, (ii) ILD materials in the structure that have a thermal conductivity greater than 0.5 W/mK up to 2000 W/mK, or (iii) metal conductors present in the semiconductor chip that have a thermal conductivity of greater than 40 w/MK in combination with ILD materials in the semiconductor chip that have a thermal conductivity greater than 0.5 W/mK up to 2000 W/mK, or any combination thereof.

17. The structure of claim 16, wherein the heat path comprises (i) and the percentage of metal structures present in the semiconductor chip is from 10% to greater than 50% of level needed for chiplet or chiplet stack function.

18. The structure of claim 16, wherein the heat path comprises (ii) or (iii) and the thermal conductivity of the ILD materials is from greater than 1 W/mK to 10 W/mK.

19. The of claim 16, wherein the heat path comprises (ii) or (iii) and the thermal conductivity of the ILD materials is from greater than 10 W/mK to 500 W/mK.

20. The structure of claim 16, wherein a first set of metal structures present in the semiconductor chip extend laterally to an edge of the semiconductor chip.
